(19) United States
(12) Patent Application Publication
(10) Pub. No.: US 2002/0011611 A1
(43) Pub. Date: Jan. 31, 2002

(54) CMOS image sensor and method of manufacture

(76) Inventors: Sen-Huang Huang, Hsinchu (TW); San-Wen Chiou, Hsinchu Hsien (TW); Sheng-Yang Huang, Hsinchu Hsien (TW)

Correspondence Address: J.C. PATENTS INC., 4 Venture, Suite 250, Irvine, CA, 92618, US

(21) Appl. No.: 09/963,201

(22) Filed: Sep. 25, 2001

Related U.S. Application Data
(62) Division of application No. 09/611,564, filed on Jul. 7, 2000.

(51) Int. Cl. H01L 27/148

(52) U.S. Cl. 257/227; 257/215; 257/226; 257/225

(57) ABSTRACT

A CMOS image sensor structure that includes a substrate, a sensing layer and a dopant layer. The substrate is formed using a first conductive type material. The sensing region is buried within the substrate. The sensing layer is a second type conductive material layer. The dopant layer is formed above the sensing layer. The dopant layer is a first type conductive material layer.

### BACKGROUND OF THE INVENTION

1. Field of Invention

The present invention relates to a complementary metal-oxide-silicon (CMOS) fabrication technique. More particularly, the present invention relates to a CMOS image sensor structure and a method of manufacturing the CMOS image sensor.

2. Description of Related Art

Most conventional image sensors have a charge couple device (CCD) that transforms light energy into electrical signals. Magnitude of the electrical signal generated normally reflects the intensity of light impinging upon the CCD. Image sensors have a broad spectrum of applications including monitors, cameras and video recorders. However, due to production cost and bulkiness of CCD, less expensive product such as a CMOS image sensor using conventional CMOS semiconductor technologies is a substitute. Besides having a lower production cost, CMOS image sensors generally have very low power consumption. Moreover, the number of components and size of a CMOS image sensor can be further reduced through higher level integration of circuits.

The basic operating unit of a CMOS image sensor is a photodiode. A photodiode is a photosensitive device (or a light-detecting device) having a P-N junction capable of converting light energy into electrical signals. Because a negative bias voltage is applied to the P-N junction, electrons in the N-type layer and holes in the P-type layer will not diffuse towards a layer of the opposite type in the absence of light. Furthermore, a depletion layer is formed at the PN junction. When a beam of light having sufficient intensity impinges upon the photodiode, electron-hole pairs will be produced. The light-generated electron-hole pairs will diffuse towards the junction area. On reaching the junction area, electrons will migrate towards the N-type layer while the holes will migrate towards the P-type layer. When enough of these electrons and holes accumulate at the electrodes close to the P-N junction, current will flow. Ideally, each photodiode unit should behave like an open circuit condition when placed in total darkness. In other words, very little current should flow in the photodiode unit in the absence of light.

FIG. 1 is a schematic cross-sectional view of a conventional image sensor. As shown in FIG. 1, the image sensor is formed by first forming a photoresist layer (not shown) over a substrate 100. The photoresist layer has a pattern that exposes the location for forming a P-well. An ion implantation is next carried out to form a P-well 102 in the substrate 100. A field isolation implant is conducted to form a P-type field isolation implant region 104 in the substrate 100. Isolation regions 106 are formed above the substrate 100. Using the isolation regions 106 as a mask, an anti-punchthrough ion implant is carried out to form a P-type punchthrough layer 108 in the substrate 108. An N-type sensing region 112 and a field effect transistor 110 that includes a gate structure and N-type source/drain regions 110a are formed in the substrate 100. The source/drain regions 110a of the field effect transistor 110 and the sensing region 112 can be formed in the same ion implant step.

Since the sensing region 112 is a P-N junction, light passing into the depletion region of the sensing region 112 will trigger the production of electron-hole pairs. Ultimately, incoming light is transformed into an electrical signal. In general, characteristics of a sensing region is directly influenced by doping concentration, doping depth and doping profile in the sensing region. In other words, the characteristic of each sensing unit is related to dosage, energy and area coverage of sensing region implant. Factors that affect properties of a sensing unit further includes:

1. Leakage current: Leakage may occur in sensing region close to the edge of the field oxide layer due to defective formation or in any damaged regions resulting from ion implant.

2. Gain: Gain of the sensing unit depends on the expanse of the depletion region in the P-N junction. Typically, a larger depletion region will produce a larger gain.

3. Slew rate: The slew rate of a sensing unit depends on depth of the P-N junction. In other words, the shallower the depth of junction, the faster will be the slew rate.

4. Uniformity: Uniformity of the sense cell is closely related to the CMOS process, the sensing cell and parameters of the transistor.

5. Quantum Efficiency: In general, quantum efficiency is determined by the minority carriers in the depletion region of the P-N junction.

The conventional sensing region 112 is formed in the P-well region 102 after the field isolation implant and the anti-punchthrough implant. Moreover, the sensing region 112 also covers a portion of the field isolation region 104 and the anti-punchthrough region 108. Hence, performance of the P-N junction within the sensing region 112 is likely affected. In addition, since the sensing region 112 and the source/drain regions 110a of the field effect transistor 110a are formed in the same ion implantation, depth and dopant concentration of P-N junction in both the sensing region 112 and the source/drain regions 110a are identical. Because of this, the sensing region 112 tends to have a small area and a high dopant concentration and sensitivity of the sensing region 112 is usually at a sub-optimal level. Furthermore, some of the negative ions lodged in the substrate 100 can be easily trapped by the sensing region 112. Moreover, electrons produced by incoming light can easily escape from the sensing region 112 leading to a higher intrinsic noise level for a conventional image sensor.

### SUMMARY OF THE INVENTION

Accordingly, one object of the present invention is to provide a CMOS sensor structure and a CMOS sensor manufacturing method capable of resolving problems such as a reduced sensing region and a high dopant concentration leading to sub-optimal sensitivity due to the formation of the sensing region together with the source/drain regions of a field effect transistor after carrying out field isolation implant and anti-punchthrough implant.

A second object of this invention is to provide a CMOS sensor structure and a CMOS sensor manufacturing method capable of resolving problems due to the trapping of free negative ions in the sensing region and the ease of light-generated electrons escaping from the sensing region leading to a high noise level for the image sensor.

To achieve these and other advantages and in accordance with the purpose of the invention, as embodied and broadly described herein, the invention provides a CMOS sensor structure. The CMOS sensor includes a substrate, a sensing region and a doped region. The substrate is formed using a first conductive type material. The sensing region is formed within the first conductive substrate using a second conductive type material. The doped region is above the sensing region. The doped region is formed using a first conductive type material. One major aspect of this invention is that the sensing region is not embedded within a well region. Hence, P-N junction depth of the sensing region is deeper than a conventional design, but dopant concentration is lighter than a conventional design. With such arrangement, performance of the image sensor will improve considerably. In addition, the formation of a doped region above the sensing region can greatly lower noise level around the image sensor.

This invention also provides a method of manufacturing a CMOS image sensor. First, a first conductive type substrate having a region for forming the desired sensor is provided. A well region is formed outside the desired sensing region. A field implant region is formed in the substrate outside the desired sensing region. An isolation region is formed above the substrate. The isolation region is formed between the well region and the desired sensing region. An anti-punchthrough implant region is formed in the substrate outside the desired sensing region. A field effect transistor is formed above the well region. A sensor layer is formed in the substrate within the desired sensing region. The sensor layer is formed using a second conductive type material. A dopant region composed of a first conductive type material is formed on the upper surface of the sensor layer. Since the said field isolation implant and anti-punchthrough implant are carried out outside the sensing region, sensitivity of the sensing region is unaffected and hence the level of performance of the image sensor is raised.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic cross-sectional view of a conventional image sensor; and

FIGS. 2A through 2F are schematic cross-sectional views showing the progression of steps for producing a CMOS image sensor according to one preferred embodiment of this invention.

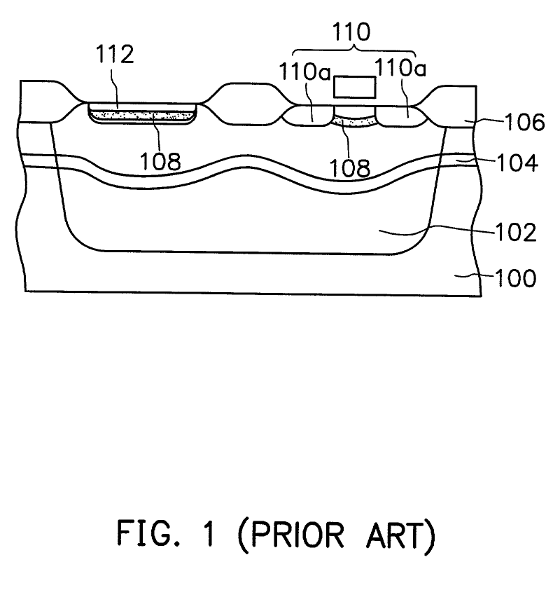

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

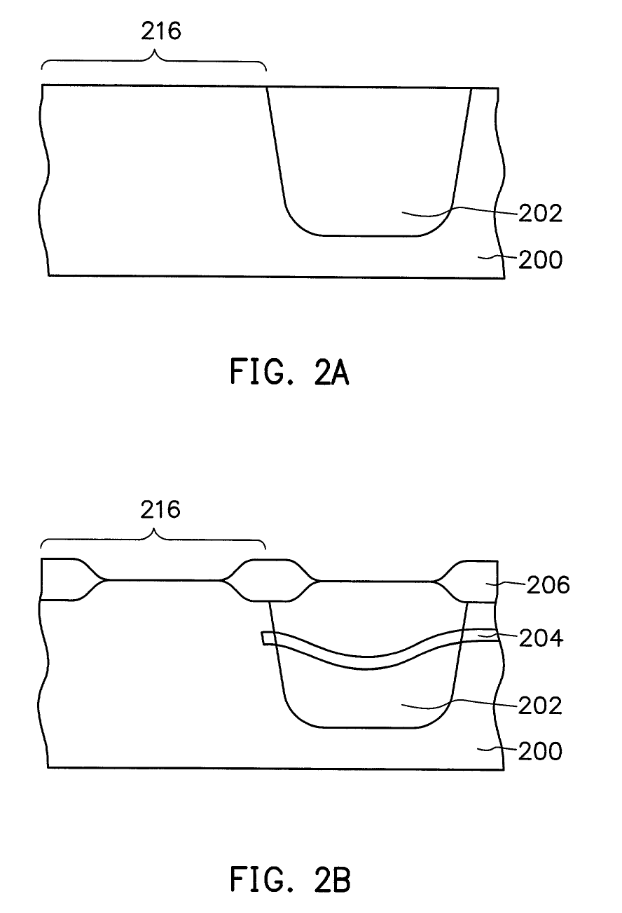

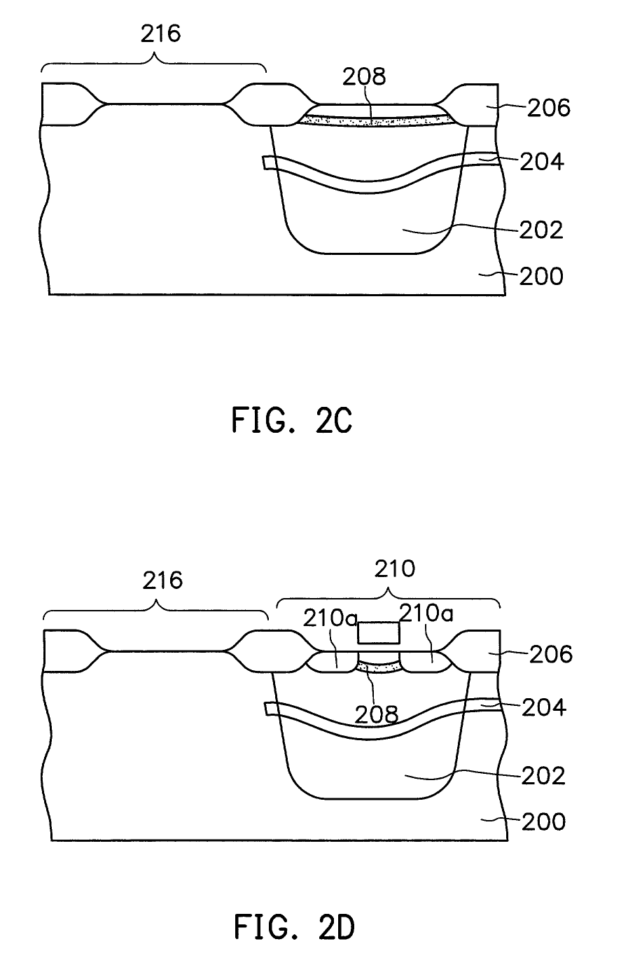

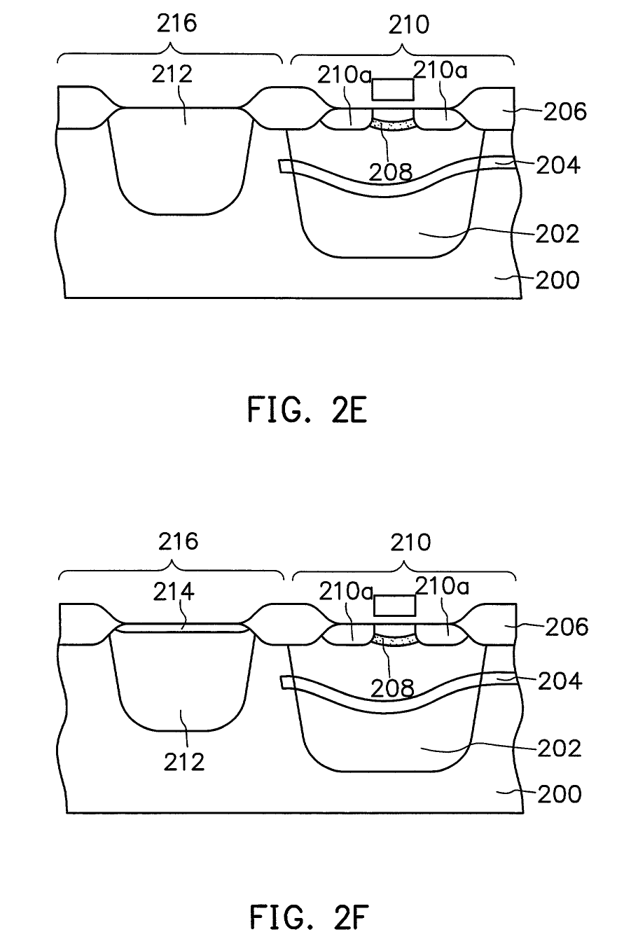

FIGS. 2A through 2F are schematic cross-sectional views showing the progression of steps for producing a CMOS image sensor according to one preferred embodiment of this invention.

As shown in FIG. 2A, a photoresist layer (not shown) is formed over a P-type substrate 200. The photoresist layer exposes a desired well region but covers the subsequently formed sensing region 216. An ion implant is carried out to form a well region 202 in the substrate 200.

As shown in FIG. 2B, a field isolation implant is carried out to form a field isolation implant region 204 in the substrate 200 outside the desired sensing region 216. Isolation regions 206 are next formed above the substrate 200.

As shown in FIG. 2C, using the isolation regions 206 as a mask, an anti-punchthrough implant is carried out to form an anti-punchthrough implant region 208 in the substrate 200 outside the desired sensing region 216.

The said well region 202, field isolation implant region 204 and anti-punchthrough implant region 208 can be formed by the following steps. First, using a photoresist layer as a mask, an ion implant is carried out to form a P-well region 202. For example, boron (B¹¹) ions having a concentration of about 10¹⁵/cm³˜2.0×10¹⁶/cm³ is used as dopants, and the implant depth is about 3˜5 μm. Preferably, the concentration of ions in the implant is about 1×10¹⁶/cm³ and the implant depth is about 4 μm. A field isolation implant is next carried out to form the P-type field isolation implant region 204. For example, boron (B¹¹) ions having a concentration of about 10¹⁶/cm³˜2.0×10¹⁷/cm³ is used as dopants, and the implant depth is about 0.4˜0.7 μm. Preferably, the concentration of ions in the implant is about 1×10¹⁷/cm³ and the implant depth is about 0.6 μm. A local oxidation is carried out to form the isolation regions 206. In a subsequent step, an anti-punchthrough implant is carried out to form the P-type anti-punchthrough implant region 208. For example, boron (B¹¹) ions having a concentration of about 10¹⁶/cm³˜2.0×10¹⁷/cm³ is used as dopants, and the implant depth is about 0.2˜0.4 μm. Preferably, the concentration of ions in the implant is about 1×10¹⁷/cm³ and the implant depth is about 0.3 μm.

As shown in FIG. 2D, a field effect transistor 210 having source/drain regions 210a thereon is formed above the well region 202. Since method of forming the field effect transistor over a substrate 200 should be familiar to those skill in the technology, detailed descriptions of the process is omitted here. The source/drain regions 210a, for example, can be an ion-doped layer formed by implanting arsenic (As⁷⁵) or phosphorus (P³¹) ions having a concentration of about 10¹⁸/cm³˜2.0×10¹⁹/cm³ to a depth of about 0.2˜0.4 μm. Preferably, concentration of the ions is about 1×10¹⁹/cm³ and the implant depth is about 0.3 μm.

As shown in FIG. 2E, an N-type sensing layer 212 is formed in the substrate 200 within the desired sensing region. The method of forming the N-type sensing layer 212 includes, for example, implanting N-type ions such as arsenic (As⁷⁵) or phosphorus (P³¹) having a concentration of about 10¹⁶/cm³˜2.0×10¹⁷/cm³ to a depth of about 0.6˜1.5 μm. Preferably, concentration of the ions is about 1×10¹⁷/cm³ and the implant depth is about 1 μm. The method of forming the sensing region 212 is a major aspect of this invention. This is because the sensing region 212 is not interfered by the steps of forming the field isolation implant region 204 and the anti-punchthrough implant region 208 earlier on. Furthermore, because the sensing region 212 is formed after the source/drain regions 210a, the sensing region 212 can have a deeper P-N junction depth while having a lighter dopant concentration. Consequently, both performance and sensitivity of image sensor will improve considerably.

As shown in FIG. 2F, a P-type dopant region 214 is formed over the sensing region 212. Dopant region 214 is formed, for example, by implanting P-type ions such as boron (B¹¹) ions having a concentration of about 10¹⁹/cm³˜2.0×10²⁰/cm³ to an implant depth of about 0.05˜0.2 μm. Preferably, the concentration of ions in the implant is about 1×10²⁰/cm³ and the implant depth is about 0.1 μm. This is another major aspect in this invention. By forming a P-type dopant region 214 above the sensing region 212, free-floating negative ions in the substrate 200 will not be trapped inside the sensing region 212 so readily. Moreover, electrons generated by incoming light will not escape from the sensing region 212 so easily. Ultimately, noise level around the image sensor will be greatly reduced and hence sensitivity will increase.

Sensitivity of the image sensor fabricated according to this invention is roughly four times that of a conventionally designed image sensor. Moreover, under the same incoming light intensity, the voltage generated by the image sensor after conversion from current is roughly three times the voltage produced by a conventional image sensor.

In this invention, a P-type substrate 200, an N-type sensing region 212 and a P-type dopant region 214 is chosen as an example. In practice, this invention can also be applied to a system with an N-type substrate, a P-type sensing region and an N-type dopant region.

In summary, major aspects of this invention includes:

1. Since the sensing region of this invention is unaffected by earlier formed field isolation implant region and anti-punchthrough implant region, performance and sensitivity of the P-N junction inside the sensing region improves.

2. The image sensing region and the source/drain regions of field effect transistor is formed in different ion implant process. Hence, a deeper P-N junction and a lighter dopant concentration in the sensing region can be obtained. Again, performance and sensitivity of the image sensor improves.

3. By forming a dopant region of a second conductive type over the sensing region in this invention, free negative ions within the substrate is prevented from trapping inside the sensing region. In addition, electrons generated by incoming light cannot so easily escape from the sensing region. Therefore, noise level around the image sensor is greatly reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A complementary metal-oxide-semiconductor (CMOS) image sensor structure, comprising:
a substrate, wherein the substrate is a first conductive type material;
a sensing region buried within the substrate, wherein the sensing region is a second conductive type material; and
a dopant region above the sensing region, wherein the dopant region is a first conductive type material.

2. The CMOS image sensor of claim 1, wherein the first conductive type material includes a P-doped material and the second conductive type material includes an N-doped material.

3. The CMOS image sensor of claim 1, wherein the first conductive type material includes an N-doped material and the second conductive type material includes a P-doped material.

4. The CMOS image sensor of claim 1, wherein the sensing region has a depth of about 0.6˜1.5 μm.

5. The CMOS image sensor of claim 1, wherein the dopant region has a depth of about 0.05˜0.2 μm.

6. The CMOS image sensor of claim 1, wherein the substrate further includes:
a well region in the substrate just outside the sensing region; and
an isolation region above the substrate between the sensing region and the well region.

7. The CMOS image sensor of claim 6, wherein the structure further includes:
a field effect transistor above in the well region, wherein the field effect transistor has a source/drain region;
an anti-punchthrough implant region in the substrate outside the sensing region; and
a field isolation implant region in the substrate outside the sensing region.

8. A method of manufacturing a CMOS image sensor, comprising the steps of:
providing a substrate, wherein the substrate is a first conductive type material layer and has a region for forming a desired sensor;
forming a well region in the substrate outside the desired sensor region;
forming an isolation region above the substrate, wherein the isolation region is formed between the well region and the desired sensor region;
forming a field effect transistor above the well region;
forming a sensor layer in the substrate within the desired sensing region, wherein the sensor layer is a second type conductive material layer; and
forming a dopant layer above the sensor layer, wherein the dopant layer is a first type conductive material layer.

9. The method of claim 8, wherein the first conductive type material includes a P-doped material and the second conductive type material includes an N-doped material.

10. The method of claim 8, wherein the first conductive type material includes an N-doped material and the second conductive type material includes a P-doped material.

11. The method of claim 8, wherein the step of forming the sensor layer includes implanting N-type ions having ion concentration of about 10¹⁶/cm³˜ to 2.0×10¹⁷/cm³ to a depth of about 0.6˜1.5 μm.

12. The method of claim 8, wherein the step of forming the dopant layer includes implanting P-type ions having ion concentration of about 10¹⁹/cm³˜ to 2.0×10²⁰/cm³ to a depth of about 0.05˜0.2 μm.

13. The method of claim 8, wherein after the step of forming the well region but before the step of forming the isolation region, further includes:
performing a field isolation implant to form a field implant region outside the desired sensing region.

14. The method of claim 8, wherein after the step of forming the isolation region but before the step of forming the field effect transistor, further includes:
performing an anti-punchthrough implant to form an anti-punchthrough implant region outside the desired sensing region.

15. A method of manufacturing a CMOS image sensor, comprising the steps of:
providing a substrate, wherein the substrate is a first conductive type material layer and has a region for forming a desired sensor;
forming a well region in the substrate outside the desired sensor region;
performing a field isolation implant to form a field isolation implant region outside the desired sensing region;
forming an isolation region above the substrate, wherein the isolation region is formed between the well region and the desired sensing region;
performing an anti-punchthrough implant to form an anti-punchthrough implant region outside the desired sensing region;
forming a field effect transistor above the well region;
forming a sensor layer in the substrate within the desired sensing region, wherein the sensor layer is a second type conductive material layer; and
forming a dopant layer above the sensor layer, wherein the dopant layer is a first type conductive material layer.

16. The method of claim 15, wherein the first conductive type material includes a P-doped material and the second conductive type material includes an N-doped material.

17. The method of claim 15, wherein the first conductive type material includes an N-doped material and the second conductive type material includes a P-doped material.

18. The method of claim 15, wherein the step of forming the sensor layer includes implanting N-type ions having ion concentration of about 10¹⁶cm³˜ to 2.0×10¹⁷/cm³ to a depth of about 0.6˜1.5 μm.

19. The method of claim 15, wherein the step of forming the dopant layer includes implanting P-type ions having ion concentration of about 10¹⁹/cm³˜ to 2.0×10²⁰/cm³ to a depth of about 0.05˜0.2 μm.
